(19) United States
(12) Patent Application Publication
(10) Pub. No.: US 2009/0308431 A1
(43) Pub. Date: Dec. 17, 2009

(54) CONCENTRATOR PHOTOVOLTAIC DEVICE; PHOTOVOLTAIC UNIT FOR USE THEREIN AND MANUFACTURING METHOD FOR THIS

(75) Inventor: Erich W. Merkle, Munchen (DE)

Correspondence Address: FURR LAW FIRM, 2622 DEBOLT ROAD, UTICA, OH, 43080, US

(73) Assignee: SOLARTEC AG, Munchen (DE)

(21) Appl. No.: 12/088,014

(22) PCT Filed: Jan. 19, 2006
(86) PCT No.: PCT/DE2006/001652

§ 371 Date: Mar. 25, 2008

(30) Foreign Application Priority Data
Sep. 30, 2005 (DE) 10 2005 047 132.3
Sep. 30, 2005 (DE) PCT/DE2006/001652

(51) Int. Cl. H01L 31/052; H01L 31/18

(52) U.S. Cl. 136/246; 29/592.1

(57) ABSTRACT

The invention relates to a concentrator photovoltaic device (10) having a plurality of photovoltaic units (22) for directly converting solar energy into electrical energy, wherein a plurality of the photovoltaic units (22) are each provided with: a light entry surface (20) formed on a first optical unit (24), a solar cell (56) which has a smaller surface expanse than the light entry surface (20) of the photovoltaic device (22), the first optical unit (24) being designed to concentrate or focus the solar radiation entering through the light entry surface (20) onto a predetermined area (34) which is determined by the smaller surface of the solar cell (56), is at a spacing from the light entry surface (20) and is smaller in area than the light entry surface (20). In order to achieve a cheaper device by the use of smaller-area solar cells, without any problems in positioning them, it is proposed according to the invention that the plurality of photovoltaic units (22) are each provided with a retaining device (30) with which the associated solar cell (56) is positioned in the predetermined area (34), in that the retaining device (30) is attached by a first end (32) to the first optical unit (24) and that the solar cell (56) is attached to an opposing second end (34) of the retaining device (30). Moreover, a photovoltaic unit for such a device and an advantageous method for producing it are described.

The invention relates to a concentrator photovoltaic device according to the preamble of the attached claim 1, as known from the article by A. W. Bett et. al: FLATCON AND FLASHCON CONCEPTS FOR HIGH CONCENTRATION PV, Proc. 19^{th} European Photovoltaic Solar Energy Conference and Exhibition, Paris, France, 2004, page 2488. In particular, the invention relates to a photovoltaic module (PV module) for directly converting light into electrical energy, wherein the incident light is concentrated before arriving on a solar cell (PV concentrator module). The invention also relates to a photovoltaic unit for a PV concentrator module of this kind. Finally, the invention relates to a method of producing a concentrator photovoltaic device of this kind.

For more details of such concentrator photovoltaic device, reference is made in particular to the German Patent Application DE 10 2005 033 272.2 by the present applicant, which is not a prior publication.

The invention is in the field of concentrator solar modules. In modules of this kind a plurality of units which concentrate direct solar radiation onto a high performance solar cell are combined in a sealed module. The solar cell generates electric current which can be used directly.

In the field of the exploitation of solar energy it has been known for about 50 years that solar energy can be converted into electric current by means of silicon. In the solar cells which are currently in common use, mono- or polycrystalline silicon is generally used. The performance of these cells is relatively poor, however, as they convert only a limited spectrum of the incident radiation into electric current. Considerable success in terms of significantly higher efficiency with more than 36% conversion of the solar radiation has been achieved in recent years with high performance PV cells made from higher valency semiconductor compounds (e.g. III-IV semiconductor material) such as gallium arsenide (GaAs), for example. One aim of the invention is to make the use of such PV cells economically attractive.

Cells of this kind based on semiconductor material may be constructed stepwise as tandem or triple cells and consequently utilise a broader light frequency spectrum. However, the production of large surface areas of such cells is extremely high-cost. The approach adopted was therefore to concentrate the incident sunlight onto a very small surface area of for example less than 1 mm². A solar cell is then only needed for this small area. This concentration means that currently the high light yield of high performance PV cells of more than 36% can be utilised. Since the system costs for solar installations are calculated according to the electrical power produced, these costs are reduced as a result of the replacement of large-area solar cells by the much cheaper concentrating optics and small but highly efficient cells. The effort involved in adjusting the system to track the movements of the sun is relatively small in relation to the increased efficiency achieved.

However, the systems used hitherto operate predominantly with relatively large Fresnel lenses with a relatively large focal length, which results in substantial thickness of the modules. Combining them into units of the required performance results in a very great weight, with the result that the requirements of the structural design of the guidance system because of for example the wind forces, are considerable. Therefore, because of the major work involved, concentrator systems of this kind have not caught on in spite of the large growth in photovoltaic current generation.

Admittedly, in recent years, systems with small Fresnel lenses have also been proposed, which in some cases also provided a more than 500-fold concentration of sunlight. In this case, however, a very large number of units are needed (e.g. about 1.5 million cells for 500 kW of power, 30% “performance” of the solar cells), in order to construct an economically viable solar power installation. Hitherto, the problem of the outward release of high concentrations of heat and the protection of the delicate solar cells from environmental influences, particularly penetrating moisture and gases, have not been solved.

The constructional problems of the exact positioning and fixing of each cell in the focal length have caused considerable work in the approaches adopted hitherto, largely gobbling up the cost savings envisaged. The problems of precise positioning limit the possible concentration and hence the size of the solar cells. The proposed systems (Bett et al reference) therefore use maximum concentrations of about 500 suns and solar cells with sides about 2.5 mm long.

The problem of precise positioning is explained hereinafter with reference to the attached FIG. 5. Even after being concentrated the light is not uniformly distributed but has a Gaussian distribution, as shown diagrammatically at reference numeral 1 in FIG. 5. x₁ shows the distance from the centre of the light spot within which about 90% of the light intensity strikes. If the positioning of the edges of the solar cell deviates substantially from the point x₁, a considerable proportion of the light intensity is lost. It is therefore important to position the solar cell as accurately as possible so that the maximum light intensity strikes the solar cell. This is considerably easier with larger solar cells but the costs for manufacturing the solar cells are then increased substantially.

Solar cells are manufactured on semiconductor wafers. These wafers are usually circular discs of the order of 10 cm or more in diameter. All the manufacturing steps needed for producing a solar cell are to be carried out from wafer to wafer, irrespective of how many solar cells are being manufactured from the wafer. Only the lithography masks would then be different. In other words: if the number of solar cells manufactured from one wafer is increased, the costs per solar cell decrease accordingly. With a solar cell having an area of 20×20 mm, only a few solar cells will fit on the surface of the wafer; in addition, large cutaway areas are left around the circular edges which cannot be used for the production of solar cells. The smaller the cross-section of the solar cell, the more solar cells fit on a wafer surface, so that far more solar cells can be made from one wafer, including around the edge of the wafer. However, the smaller the solar cell the more accurate the positioning must be.

Exact positioning of the solar cells to the concentrator lens can be carried out passably in laboratory tests. However, it is important to provide constructions and manufacturing methods with which even the smallest possible solar cells produced in practice can be used so as to exploit the maximum possible light intensity at the lowest possible cost for as long as possible.

The precise positioning of the solar cells in the prior art is influenced by a number of factors, some of which are variable during operation, and are therefore difficult to control in practice.

The problem of the invention is to construct a concentrator photovoltaic device having the features of the preamble of the attached claim 1 such that higher concentrations can be achieved, and solar cells with smaller surface areas can be used, without any problems arising with the positioning. In all, as a result, it should be possible to use substantially cheaper systems to assemble the modules, while the systems for guiding the modules should be simpler and cheaper to produce.

This problem is solved by a concentrator photovoltaic device having the features of the attached claim 1.

Advantageous embodiments of the invention are the subject of the dependent claims. An individual photovoltaic unit for a photovoltaic device of this kind is the subject of the independent claim. An inexpensive method of production is recited in the other independent claim.

The invention therefore provides a concentrator photovoltaic device having a plurality of photovoltaic units for directly converting solar energy into electrical energy. The numerous photovoltaic units are each provided with a first optical unit on which is formed a light entry surface, and with a solar cell which has a smaller surface expanse than the light entry surface of the respective photovoltaic unit. The first optical unit serves to concentrate or focus the solar radiation entering through the light entry surface onto a given area which has a small surface area in relation to the light entry surface and is determined by the smaller surface area of the solar cell. Because of the focusing lens of the first optical unit the predetermined area onto which the first optical unit focuses the incident solar radiation is formed at a corresponding distance from the light entry surface.

The concentrator modules known previously, as being developed at present under the brand name “Flatcon” by Fraunhofer-Gesellschaft, Institut Solarenergiesysteme, and made ready for mass production, are also of similar construction.

However, whereas in the known concentrator modules a transparent surface with a plurality of fields which form the individual first optical units is constructed as one side of a box-shaped structure, and an endplate forms the opposing second side of the box, it is envisaged according to the invention that the plurality of photovoltaic units are each provided with their own retaining device with which the associated solar cell is positioned in the predetermined area. The retaining device is secured at a first end to the first optical unit and the solar cell is attached to the opposite second end of the retaining device.

The reason why such a construction has considerable advantages in terms of possibly reducing the size of the solar cell without causing problems with positioning is explained in more detail below:

According to the present proposals, power plants for supplying energy are to be fitted with concentrator modules of this kind. The ambitious plans are directed at building such power plants in coastal areas where there is a high solar radiation. Accordingly it is to be assumed that in practice the concentrator modules will be subjected to considerable fluctuations in temperature. In addition to the natural temperature variations occurring in such regions the considerable heating caused by the concentration of the incident light also has to be considered. Accordingly, temperature variations of more than 100° C. must be expected on the concentrator modules. In the previously known construction in the form of a box in which one side is constructed as a Fresnel lens and the other side is a carrier plate for the solar cells, the end walls of the box positioning the two panels relative to one another and having to be hermetically sealed in order to shield the delicate solar cell surfaces, this creates considerable problems as the materials have different temperature expansion coefficients. Consequently in response to temperature variations the relative position of the solar cells to the matching first optical units varies accordingly. This problem is exacerbated by the large enclosed space in which light is concentrated and which is therefore heated up accordingly.

It must also be borne in mind that the incident light is concentrated in the form of a Gaussian distribution, as illustrated by reference numeral 1 in FIG. 5. About 90% of the irradiated energy is found within the distances represented by x₁ to x₁ from the centre of the light intensity.

In addition to the problems with the different temperature expansions of the materials used there are also possible errors in placing the individual solar cells in the focus of the primary optics. Moreover, errors in the so-called tracker alignment result in possible misalignment of the position of the solar cells to the centre of the light intensity. The term “tracker alignment” covers the guidance of the solar modules towards the sun and the correcting of the position of the solar modules in response to environmental influences such as wind, in particular. Other faults may occur during the assembly and in the event of thermal expansion of the support structure by which the individual concentrator solar modules are held.

As all these possible faults affected possible misalignments of the solar cells with regard to the optical units, relatively large-area solar cells had to be used in previous systems if a high light yield was actually to be achieved.

In the construction according to the invention, the faults mentioned have much less effect on the relative position of the solar cells to the first optical unit. According to the invention, each individual optical unit has its own retaining device allocated to it, which positions the associated solar cell relative to the respective first optical unit. This retaining device is also attached to the first optical unit.

Faults caused by different degrees of thermal expansion of the materials thus only have an effect within the small system of each photovoltaic device. Each individual photovoltaic device forms its own retaining system, so that the heat expansion errors are not added together over the entire area, as in the prior art. Thermal expansions of the walls of the concentrator module thus no longer affect the position of the individual solar cells.

Thanks to the individual retaining devices, moreover, the precise location at which each individual solar cell is to be placed can be predetermined more satisfactorily, so that errors in placing the individual solar cells in the focus of the primary optics are reduced. According to the invention, special care is needed only in placing the respective retaining device. If errors occur at this point, this only affects the respective photovoltaic unit and not the entire concentrator module, i.e. the entire photovoltaic device.

The retaining structure chosen also has the advantage that the individual solar cells are easily accessible from behind for the purpose of the electrical connections. Also, as the solar cells are secured at the front by means of the retaining devices, there is plenty of room to provide cooling fins or similar cooling structures.

Advantageously, the retaining device has a cavity within which the light rays of the sunlight focused by the first optical unit can propagate from the first optical unit to the solar cell. Consequently, the retaining device has no effect whatever on the unimpeded propagation of light, even though the retaining device is located in the space between the plane of the light entry surfaces and the plane of the solar cells. The cavity may be empty or may be filled with any desired transparent medium.

In accordance with the propagation of the concentrated light from the light entry surface to the predetermined area, the retaining device is preferably shaped conically tapering from the first end to the second end. As a result the retaining device may be made from remarkably little material, on the one hand. On the other hand, it is thus possible to determine the position of the second end which fixes the location of the solar cell precisely, so that there is no scope for ambiguity in the assembly. It is particularly preferable for the retaining device to be in the form of a truncated cone or truncated pyramid for this purpose. The truncated pyramid shape is particularly preferred for the following reasons. In order to focus as much light falling on the concentrator module as possible on the individual solar cells, the optical units are preferably constructed as individual fields of a transparent panel, as is fundamentally known in the art. The individual fields are of square or rectangular shape in order to fit closely one against the other. Each field is constructed on the inside so that light entering through the outside (the light entry surface) is focused on a point. In accordance with the shape of these individual fields, the retaining devices may also be constructed as truncated pyramids and may be arranged close together on the inside of the transparent panel without interfering with one another. The pyramid shape can easily be produced for example from plastics by injection moulding, while if weaker materials are used the edges of the pyramid shape have a stabilising effect. As a result the apex of the pyramid can easily be positioned in the vicinity of the focus of the first optical unit.

In a particularly preferred embodiment of the invention, on the second end of the retaining device there is a second optical unit which further concentrates the incident light focused through the first optical unit. The solar cell is then preferably disposed underneath this second optical unit. The combination of a first optical unit and second optical unit is able to concentrate the light entering through the light entry surface such that only a small area of even a small-surface solar cell is irradiated. Tests have shown that a high energy yield is achieved even if only a part of the small-surface solar cell is irradiated, but with a correspondingly more concentrated light. Owing to the fact that only a small proportion of the solar cell is irradiated, there is a greater probability that this smaller spot of light will still remain within the effective surface of the solar cell even in the event of misalignment. Because of the retaining device, it is also possible to achieve exact positioning of the second optical unit relative to the first optical unit and also exact positioning of the solar cell relative to the two optical units.

Another major problem with the concentrator modules is the possible risk of soiling of the solar cells. As only small areas are utilised, even small amounts of soiling, such as dust particles or moisture, can have a major effect on the performance. Screening the effective solar cell surface from the environment thus constitutes a major problem in all these concentrator modules. In the advantageous embodiment of the invention with the second optical unit, as mentioned above, the effective surface area of the solar cell can be placed directly on the second optical unit and thus sealed by this second optical unit. In this case the retaining device may also be formed, for example, by a number of rods which accordingly position the second optical unit with the solar cell attached thereto. Alternatively, various openings may be provided in a casing of the retaining device. This construction would have the advantage that any thermal expansion of a medium located in a cavity enclosed by the retaining device has no effect on the stability and position of the retaining device, as the medium (such as air) is able to escape through the openings. However, it is particularly advantageous in terms of the required cleanliness of the effective solar cell surface if the retaining device has a closed outer surface. This prevents dirt or moisture from reaching the effective solar cell surface. Advantageously, the first optical unit, the retaining device and the solar cell enclose a sealed volume, the retaining device being open at the first and second ends and being closed off at these ends by the first optical unit and the solar cell, respectively.

As a result, the module may be constructed to be open at the back to facilitate access. Cooling medium can thus easily be supplied and efficiently cooled on the enlarged surface area provided by the retaining devices.

With a construction of the retaining device in the form of a truncated cone or truncated pyramid, the retaining device is accordingly shaped like a funnel or small cone. This also has major advantages for the manufacturing process. For arranging and positioning the second optical unit, for example, the second optical unit may be constructed as a lens the side walls of which are constructed to correspond to the inner wall of the apex of the truncated cone or pyramid. All that is needed is to provide the lens with some adhesive at these side walls and to drop it into the funnel from above. In this way the lens forming the second optical unit can be correctly positioned at the same time.

In order to position the retaining device such that it automatically fits with the first optical unit, a special positioning element may be arranged on the first optical unit. This is advantageously placed on the inner surface opposite the light entry surface and directed towards the solar cell, where the retaining device is secured. If the retaining device is constructed as a truncated cone or truncated pyramid, a groove structure corresponding to the edge shape of the retaining device at the first end may be formed on this inner surface, for example. In order to secure the first end all that it needed is to apply adhesive to the groove or edge and to insert the edge in the groove. In this way, by a centring interlocking engagement, the retaining device is suitably aligned with the first optical unit. Instead of the grooves described, however, it is also possible to use other positioning elements, e.g. projections engaging in the first end, which have the same effect.

If the retaining device encloses a sealed volume, it may happen, during intensive heating, that the medium contained in the volume expands and presses against the outer surfaces of the retaining device. In order to prevent this causing misalignment of the solar cell and first optical unit, the retaining device is preferably divided with reinforcements to stiffen it. However, it is also possible to evacuate the inner volume or fill it with a gas which will expand only a little.

Thus, with the construction according to the invention, solar energy can be concentrated onto high performance solar cells in order to convert the solar energy therein into electrical current or heat energy. The invention thus allows economic utilisation of the high efficiency of multi-stage solar cells made of semiconductor material in light conversion. Preferably the concentration of the sunlight is carried out by means of an optical unit which is mounted on the underside of a panel transparent to sunlight.

The light rays focused by the first optical unit preferably strike a second optical unit at a spacing from the first optical unit, and also referred to as a secondary optic, which serves to further concentrate and focus the light onto a solar cell which is very small in relation to the size of the light entry surface. The exact positioning of the very small solar cell is carried out by means of a clamping unit connected to the light entry surface. With the construction described here it is possible to use very small solar cells, even solar cells with sides less than 0.5 mm long are possible. As a result, the high costs of multi-stage solar cells become insignificant. Solar systems equipped according to the invention for generating current therefore require substantially lower investment costs and smaller surface areas.

Compared with the known concentrator units with up to a 500-fold construction, as described at the beginning, using the construction according to the invention concentrations of more than 2,000 up to 10,0000-fold compared with normal sunlight are made possible. The above-mentioned solar cells with sides less than 0.5 mm long require a surface area of the very expensive semiconductors of only 0.25 mm² as against the 6.5 mm² of the known solar cells (e.g. in the FLATCON system). The smaller surface area additionally means that on a wafer the edges of the wafer are better utilised. The surface area specified corresponds to only 4% of the area that was previously needed; thus, only about 5% of the previous costs of solar cells are applicable. Nevertheless, because of the possibility of positioning the solar cells more accurately, a higher tolerance can be provided in the guidance of the solar cell modules. Whereas in the concentrator modules known previously guidance had to be exact within ±0.5 angular degrees, the accuracy of guidance with the construction according to the invention has to be only ±3 angular degrees.

As a result the invention makes it possible to use substantially cheaper systems to assemble the modules and substantially cheaper systems for tracking relative to the sun. For this reason, too, a substantial reduction in costs can be expected. Therefore, the invention represents a major step towards the industrialisation of this valuable environmentally helpful technology.

Advantages of the invention or the preferred embodiments thereof are as follows:
By using a secondary optic with special optical properties it is possible to achieve tight focusing of the incident sunlight onto an extremely small area.
The secondary optic can be constructed and arranged so that even if there are deviations in the angle of the perpendicularly incident sunlight by a number of angular degrees it will still achieve exact beam formation and focusing onto a predetermined point.
As a result of the construction of a retaining device attached to the edge of the respective light entry surface, the solar cells can be positioned precisely in the respective focal point, while additionally a switching and heat conducting panel can be mounted on the solar cells.
The construction and positioning of the secondary optic make it possible to achieve a gastight seal directly with the solar cell, in order thereby to protect the very delicate surface of the solar cell.
The construction and fitting of a heat conducting panel for in each case only one rigidly fixed photovoltaic device (concentrator unit) ensures that the expansion of the various materials which occurs as a result of high temperature differences leads only to negligible stresses—in contrast to concentrator modules in which a plurality of solar cells are mounted fixedly on a heat conducting panel or base plate.

An embodiment exemplifying the invention is described hereinafter with reference to the attached drawings, wherein:

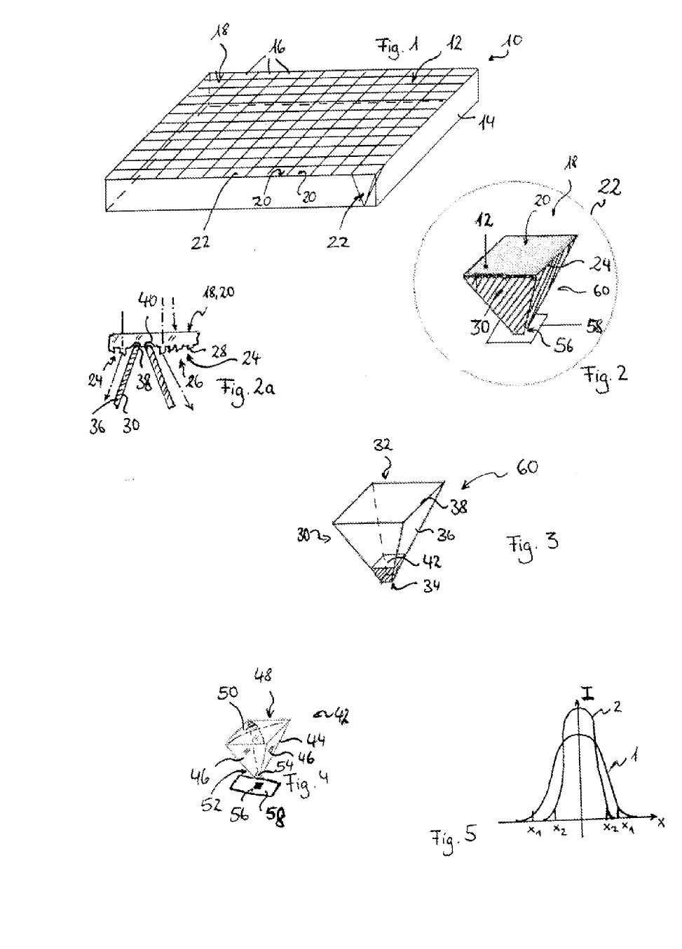

FIG. 1 shows a highly simplified perspective view of a concentrator photovoltaic device in the form of a concentrator module having a plurality of individual photovoltaic units;

FIG. 2 is a detailed view, magnified compared with FIG. 1, of an individual photovoltaic unit of the concentrator device in FIG. 1;

FIG. 2a is a section through the concentrator module in the region of the boundary between two photovoltaic units and in the region of the light entry surface;

FIG. 3 is a perspective view of a retaining device with a secondary optic, used in the photovoltaic unit of FIG. 2;

FIG. 4 shows a view, magnified compared with FIG. 3, of the secondary optic used in FIG. 3; and

FIG. 5 shows highly diagrammatic representations of the light intensities according to the prior art, compared with the distribution of light intensity in the device shown here.

FIG. 1 shows a photovoltaic device in the form of a concentrator module 10. The concentrator module 10 has a transparent panel 12 which is secured by means of a frame 14 and can be positioned as perpendicularly as possible to the irradiation of sunlight by means of device of a known kind which are not shown in detail. The transparent panel 12 is divided into a plurality of square or rectangular fields 16, which form, on their outer sides 18 facing the sun, light entry surfaces 20 of individual photovoltaic units in the form of individual concentrator units 22. Each of the fields 16 thus represents a single concentrator unit 22, so that the concentrator module 10 as a whole is made up of a plurality of concentrator units 22. Each concentrator unit 22 uses part of the transparent panel 12, so that the concentrator units 22 are joined together by means of the transparent panel 12.

FIG. 2 shows a more detailed view of an individual concentrator unit 22, as an example of the plurality of concentrator units 22. Each of the fields 16 has, on the inside opposite the outer side 18, a first optical unit in the form of a primary optic 24 with which all the light entering through the light entry surface 20 is concentrated onto one focus per concentrator unit 22. To form the primary optic, a Fresnel lens is formed on each of the fields 16, the field 16 being provided on the inside 26 with corresponding structures.

Attached to the inside 26, in addition to the Fresnel structures 28 which serve to focus the light, there is also a retaining device 30. The retaining device 30 is constructed in the form of the shell of a truncated pyramid, as is most clearly shown in FIG. 3. The base area of the truncated pyramid corresponds to the shape of the fields 16. A first end 32 is constructed to be open at the base of the truncated pyramid. The second end 34, which is constructed to be correspondingly smaller in area at the apex of the truncated pyramid, is also open. The outer surface 36 is totally closed all round. The walls of the retaining device 30 are preferably made of plastics, although other materials such as sheet metal are also possible.

As is most clearly shown in FIG. 2a, the edges of the retaining device 30 formed at the first end 32 are fixed in corresponding grooves 40 which are formed on the inside 26 of the transparent panel in the edge region of each field 16 in a shape which complements the edges 38. The edges 38 are adhesively bonded in the grooves 40, for example.

A second optical unit in the form of a secondary optic 42, shown more clearly in FIG. 4, is fixed in the apex of the truncated pyramid shape of the retaining device 30. The secondary optic 42 is formed by a body 44 of an optical material such as glass, in particular, the sidewalls 46 of which are matched to the interior of the retaining device 30 in the region of the apex of the truncated pyramid. Accordingly, the body 44 is also shaped like a truncated pyramid in the embodiment shown. On the base surface 48 of this truncated pyramid there is a convexity 50 which forms a lens for further concentrating the irradiated light. A planar surface 54 is formed on the correspondingly smaller-area apex of the pyramid shape of the body 44. A solar cell 56 shown in FIG. 4 at a spacing from this surface 54, purely for illustration purposes, is connected to the surface 54 such that this surface 54 covers the light-sensitive surface of the solar cell 56 in a sealing manner. The body 44 of the secondary optic 42 is adhesively bonded by its sidewalls 46 to the outer surface 36 of the retaining device 30. In this way the solar cell 56 is also fixedly connected to the retaining device 30 and positioned precisely relative to the primary optic 24.

As can be seen from FIGS. 2 and 4, the solar cell 56 is attached to a heat conducting panel 58 which is provided with further switching and connecting elements that are not shown in detail but are sufficiently well-known.

The following procedure is used in the manufacture of the concentrator module 10.

First, the transparent panel 12 is produced in such a way that it is flat on the outside and is provided on the inside with the individual Fresnel structures 28 and the grooves 40 on each of the individual fields 16.

The retaining device 30 is produced by a suitable manufacturing process such as plastics injection moulding, for example, from a material with the lowest possible coefficient of expansion.

In addition, the body 44 of the secondary optic 42 is produced with an exact convexity 50, then the sidewalls 46 of the body are provided with adhesive and inserted in the retaining device 30 via the open first end 32. Thanks to the inner wall of the retaining device 30 which fits in complementary manner, and the sidewalls 46, the secondary optic 42 is automatically positioned correctly as it is inserted. As a result, the optical unit 60 shown in FIG. 3 is obtained, formed from the retaining device 30 and secondary optic 42. This optical unit 60 is then attached to the inside of the transparent panel and hence to the primary optic 24 by inserting the edges 38 into the grooves 40. This connection is secured by suitable jointing techniques, e.g. adhesive bonding. In one embodiment the connection is made while the transparent panel is still soft, so that once the transparent panel hardens a fixed connection is automatically obtained between the transparent panel 12 and optical unit 60.

The solar cell 56 and the other switching and connecting elements are mounted on the heat conducting panel 58, connected up and tested. The heat conductivity of the heat conducting panel, which is preferably made of metal, can be deliberately chosen by using particularly conductive metal materials and/or different thicknesses of material. The heat conductivity can also be varied subsequently by the additional mounting of conductive sheets of material. In some embodiments which are not shown here, cooling fins are also provided on the heat conducting panel.

The solar cell 56 is then connected, together with the heat conducting panel 58 attached thereto, to the lower surface 54 of the secondary optic 42 and optionally fixed with the retaining unit.

FIG. 5 shows the distribution of light by way of example in the region of a solar cell 56 without using the secondary optic 42 bearing reference numeral 1 and with the use of the secondary optic 42 bearing reference numeral 2. By means of the exactly positioned secondary optic 42 it is possible to narrow down the light intensity such that 90% of the light intensity does not strike, as before, in broader limits between x₁-x₁, but rather in narrower limits between x₂-x₂. Thus, for the same surface area of solar cells, a larger proportion of the light intensity still remains within the region of the light-active surface of the solar cell even if there is minor misalignment of the solar cell with the first optical unit.

Thanks to the exact positioning by means of the retaining device 30, particularly in conjunction with the secondary optic 42, it is thus possible to use an overall smaller surface area of solar cells 56 while at the same time greater tolerances are permissible in the alignment of the transparent panel 12 with the irradiated light.

### LIST OF REFERENCE SIGNS

10 Concentrator module (photovoltaic device)
12 Transparent panel
14 Frame
16 Fields
18 Outer side
20 Light entry surfaces
22 Concentrator unit (photovoltaic unit)
24 Primary optic (first optical unit)
26 Inside
28 Fresnel structure
30 Retaining device
32 First end
34 Second end
36 Outer surface
38 Edges
40 Grooves
42 Secondary optic
44 Body
46 Side walls
48 Base surface
50 Convexity
52 Apex
54 Surface
56 Solar cell
58 Heat conducting panel
60 Optical unit

1. Concentrator photovoltaic device (10) having a plurality of photovoltaic units (22) for directly converting solar energy into electrical energy, wherein a plurality of the photovoltaic units (22) are each provided with: a light entry surface (20) formed on a first optical unit (24), a solar cell (56) which has a smaller surface expanse than the light entry surface (20) of the photovoltaic unit (22), the first optical unit (24) being designed to concentrate or focus the solar radiation entering through the light entry surface (20) onto a predetermined area (34) which is determined by the smaller surface of the solar cell (56), is at a spacing from the light entry surface (20) and is smaller in area than the light entry surface (20),
characterised in that the plurality of photovoltaic units (22) are each provided with a retaining device (30) with which the associated solar cell (56) is positioned in the predetermined area (34), in that the retaining device (30) is attached by a first end (32) to the first optical unit (24) and that the solar cell (56) is attached to an opposing second end (34) of the retaining device (30).

2. Photovoltaic unit according to claim 1,
characterised in that,
the retaining device (30) comprises a hollow cavity.

3. Photovoltaic unit according to one of the preceding claims,
characterised in that,
the retaining device (30) is constructed so as to taper at least on the inside from the first end (32) towards the second end (34).

4. Photovoltaic unit according to claim 3,
characterised in that,
the retaining device (30) is constructed in the manner of a truncated cone or truncated pyramid.

5. Photovoltaic device according to one of the preceding claims,
characterised in that,
secured to the second end (34), is a second optical unit (42) for further concentrating the incident light focused through the first optical unit (24).

6. Photovoltaic unit according to one of the preceding claims,
characterised in that,
the retaining device (30) has a closed outer surface (36).

7. Photovoltaic unit according to one of the preceding claims,
characterised in that,
the retaining device (30) is open at the first (32) and second end (34).

8. Photovoltaic unit according to one of the preceding claims,
characterised in that,
the first optical unit (24) comprises, on its side (26) opposite the light entry surface (20) and directed towards the solar cell (56), a positioning element (40) for positioning the first end (32) of the retaining device (30).

9. Photovoltaic device according to one of the preceding claims,
characterised in that,
the first optical unit (24), the retaining device (30) and the solar cell (56) or an element (58, 44) connected to the solar cell (56) enclose a sealed volume.

10. Photovoltaic device according to one of the preceding claims,
characterised in that,
the retaining device (30) is provided with reinforcements for stiffening it against deformations caused by environmental or temperature influences.

11. Photovoltaic unit (22) for a concentrator photovoltaic device (10) according to one of the preceding claims,
characterised by
a first optical unit (24) with a light entry surface (20),
a solar cell (56), which has a smaller surface expanse than the light entry surface (20),
the first optical unit (24) being constructed so as to concentrate or focus the solar radiation entering through the light entry surface (20) onto a predetermined area (34) which is determined by the smaller surface of the solar cell (56), is at a spacing from the light entry surface (20) and is smaller in area that the light entry surface (20), characterised in that,
the solar cell (56) is positioned in the predetermined area (34) by means of a retaining device (30) which is attached by a first end (32) to the first optical unit (24), while the solar cell (56) is attached to an opposing second end (32) of the retaining device (30).

12. Method for producing a concentrator photovoltaic device (10) according to one of claims 1 to 10,
characterised by
a) the provision of a transparent panel (12) which comprises a plurality of fields (16) in which first optical units (24) are formed for focusing the light entering through the individual fields (16) of the transparent panel (12) onto smaller predetermined areas (34),
b) the provision of one retaining device (30) for each field (16) to be utilised, for precisely positioning solar cells (56), smaller in area than the fields (16), in the predetermined areas (34),
d) attaching the retaining devices (30) to the side (26) of the transparent panel (12) which is opposite the light entry side (18), and
e) attaching a solar cell (56) to each retaining device.

13. Method according to claim 12,
characterised in that,
step a) comprises:
providing positioning aids (40) for accurately positioning the retaining devices (30) on the transparent panel (12).

14. Method according to one of claims 12 or 13,
characterised in that,
step b) comprises:
producing the retaining device (36) in the form of a truncated cone or truncated pyramid having an outer casing (36) and an open first end (32) and a second end (34) which has a smaller area than the first end.

15. Method according to claim 14
characterised by the step which is to be carried out between steps b) and d), namely:
c) inserting a second optical unit (42) adapted to fit the inside of the outer casing in the region of the second end (34), for abutment on the outer casing, said second optical unit (42) being designed to further concentrate the light focused through the first optical unit (24) onto a smaller area of the solar cell (56), through the first end, and attaching the same on the inside to the second end (34).
